(19) United States
(12) Patent Application Publication
(10) Pub. No.: US 2026/0182262 A1
(43) Pub. Date: Jun. 25, 2026

(54) METHOD FOR MANUFACTURING SEMICONDUCTOR DEVICE

(71) Applicant: CANON KABUSHIKI KAISHA, Tokyo (JP)

(72) Inventors: TETSUYA KIMURA, Tokyo (JP); YOSHIHISA KAWAMURA, Kanagawa (JP); MASAKI SAITO, Tochigi (JP); AKIRA MATSUZAKI, Kanagawa (JP); MAYU ISHIKAWA, Kanagawa (JP)

(21) Appl. No.: 19/423,937

(22) Filed: Dec. 17, 2025

(30) Foreign Application Priority Data
Dec. 24, 2024 (JP) 2024-227251

(51) Int. Cl. H10P 10/00; H10P 52/40; H10P 58/00

(52) U.S. Cl. CPC H10P 10/12; H10P 52/407; H10P 58/20

(57) ABSTRACT

A method for manufacturing a semiconductor device including a first substrate, on which a plurality of parts is arranged, and a plurality of chips disposed on the first substrate to correspond to the respective parts. The method includes preparing a member including the first substrate and the plurality of chips disposed on the substrate, forming a first film having a flat top surface by applying a precursor onto the member so that an amount of precursor applied onto the chips is less than an amount of precursor applied onto another portion, and dicing the member, wherein the forming the first film includes bringing a superstrate into contact with the precursor.

### BACKGROUND

### Field of the Technology

The present disclosure relates to a method for manufacturing a semiconductor device.

### Description of the Related Art

There has been known a method for manufacturing semiconductor devices by arranging a plurality of chips on a substrate such as a semiconductor wafer, followed by dicing. Japanese Patent Laid-Open No. 2022-089275 describes a manufacturing method in which a plurality of chips arranged on a semiconductor wafer is buried in an oxide film and then a support substrate is provided thereon.

### SUMMARY

In Japanese Patent Laid-Open No. 2022-089275, the step of burying the plurality of chips and a planarization step after the burying step are not examined in detail. The present disclosure is directed to providing a technique advantageous to a method for manufacturing a semiconductor device, in which a plurality of chips is arranged on a substrate.

According to an aspect of the present disclosure, there is provided a method for manufacturing a semiconductor device including a first substrate, on which a plurality of parts is arranged, and a plurality of chips disposed on the first substrate to correspond to the respective parts. The method includes preparing a member including the first substrate and the plurality of chips disposed on the substrate, forming a first film having a flat top surface by applying a precursor onto the member so that an amount of precursor applied onto the chips is less than an amount of precursor applied onto another portion, and dicing the member, wherein the forming the first film includes bringing a superstrate into contact with the precursor.

According to another aspect of the present disclosure, there is provided a method for manufacturing a semiconductor device including a first substrate, on which a plurality of parts is arranged, and a plurality of chips disposed on the first substrate to correspond to the respective parts. The method includes preparing a member including the first substrate and the plurality of chips disposed on the first substrate, forming a first film having a flat top surface by applying a precursor onto the member so that an amount of precursor applied onto the chips is less than an amount of precursor applied onto another portion, and dicing the member, wherein the forming the first film includes curing the precursor with a second substrate in contact with the precursor, and bonding the second substrate to the first film.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic diagram illustrating a configuration of a planarization apparatus.

FIGS. 2A, 2B, and 2C are schematic diagrams for describing planarization processing.

FIGS. 3A and 3B are schematic diagrams for describing a method for manufacturing a semiconductor device according to a first embodiment.

FIGS. 4A, 4B, and 4C are schematic diagrams for describing the method for manufacturing a semiconductor device according to the first embodiment.

FIGS. 5A, 5B, and 5C are schematic diagrams for describing the method for manufacturing a semiconductor device according to the first embodiment.

FIGS. 6A and 6B are schematic diagrams for describing a method for manufacturing a semiconductor device according to a second embodiment.

FIGS. 7A, 7B, and 7C are schematic diagrams for describing the method for manufacturing a semiconductor device according to the second embodiment.

FIGS. 8A and 8B are schematic diagrams for describing the method for manufacturing a semiconductor device according to the second embodiment.

FIGS. 9A, 9B, and 9C are schematic diagrams for describing application examples of a semiconductor device according to a third embodiment.

### DESCRIPTION OF THE EMBODIMENTS

Embodiments will be described below with reference to the drawings. The following embodiments are not intended to limit the disclosure set forth in the claims. While the embodiments describe a plurality of features, not all of these features are necessarily essential to the disclosure, and multiple features may be freely combined. In the attached drawings, the same or similar components are denoted by the same reference numerals, and redundant descriptions may be omitted.

The embodiments of the present disclosure will be described in detail below with reference to the drawings. In the following description, terms indicating specific directions and positions (for example, “top”, “bottom”, “right”, “left”, and other terms including these) are used as needed. These terms are used to facilitate understanding of the embodiments with reference to the drawings, and the technical scope of the present disclosure is not limited by the meanings of the terms.

As employed herein, a plan view refers to a view in a direction perpendicular to the top surface of a semiconductor substrate. A sectional view refers to a plane in a direction perpendicular to the top surface of a semiconductor substrate. If the top surface of the semiconductor substrate is a microscopically rough surface, a plan view is defined with reference to the top surface of the semiconductor substrate when viewed macroscopically. The top surface of a semiconductor substrate shall refer to the surface where elements formed on the semiconductor substrate, such as transistor gates, are located, or where connections with contact plugs are located.

Expressions such as “A or B”, “at least one of A and B”, “at least one of A and/or B”, and “one or more of A and/or B” shall include all possible combinations of the enumerated items unless explicitly defined otherwise. In other words, the foregoing expressions are understood to disclose all the following cases: where at least one A is included, where at least one B is included, and where at least one A and at least one B are both included. The same applies to combinations of three or more elements.

The relationship “substantially equal” in the present disclosure will be described. Items designed to be equal can differ slightly due to manufacturing errors. This “substantially equal” covers such slight differences occurring from manufacturing errors.

### First Embodiment

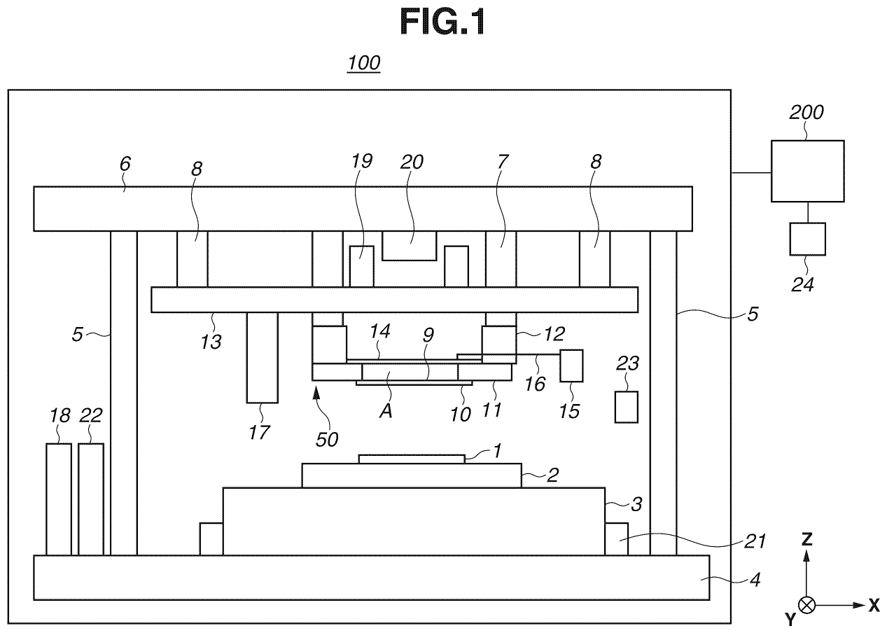

FIG. 1 is a schematic diagram illustrating a configuration of a planarization apparatus 100 according to the present embodiment. Directions are illustrated in an XYZ coordinate system with the horizontal plane as an XY plane. A substrate 1 that is an object to be processed is typically placed on a substrate stage 3 with its surface parallel to the horizontal plane (XY plane). In the following description, mutually orthogonal directions within a plane along the surface of the substrate 1 will therefore be represented by as an X-axis and a Y-axis, and a direction perpendicular to the X-and Y-axes by a Z-axis. Directions parallel to the X-axis, the Y-axis, and the Z-axis of the XYZ coordinate system will hereinafter be referred to as an X direction, a Y direction, and a Z direction, respectively. A direction of rotation about the X-axis, a direction of rotation about the Y-axis, and a direction of rotation about the Z-axis will be referred to as a θX direction, a θY direction, and a θZ direction, respectively. As will be described below, the substrate 1 is a member to which semiconductor processes can be applied. Examples include a semiconductor wafer, a semiconductor wafer with wiring structures, a glass substrate with elements, and a metal substrate.

An underlying pattern on the substrate has an uneven profile due to patterns formed in previous processes. In particular, with the recent trend toward multilayer structures in memory elements, some process substrates have come to have step heights of around 100 nm. Step differences resulting from gentle undulation of the entire substrate can be corrected by a focus tracking function of the scan exposure apparatus used in photolithographic processes. By contrast, fine-pitch unevenness falling within the exposure slit area of the exposure apparatus can deviate from the depth of focus (DOF) of the exposure apparatus. Conventionally, techniques for forming a planarization layer or for performing planarization processing, such as Spin on Carbon (SOC) and chemical mechanical polishing (CMP), have been used as a method for smoothing the underlying pattern of substrates. However, the conventional techniques have the issue of insufficient planarization performance. For example, manufacturing processes have been advancing to new technology nodes like 22 nm, 16 nm, 14 nm, and 10 nm. Planarization layers sufficient for practical use with previous-generation nodes may not be practically viable for subsequent nodes. For example, the surface irregularities of planarization layers acceptable for the previous nodes may not be tolerated for the subsequent nodes. Moreover, CMP entails high process cost and can only be applied to limited processes, while underlying unevenness tends to increase further in the future because of multilayering.

To solve such issues, a planarization apparatus that planarizes substrates using imprinting technique is being studied. The planarization apparatus locally or entirely planarizes the substrate surface by bringing a flat surface of a member, or a non-patterned member (planar template), into contact with an uncured composition supplied onto the substrate in advance. The composition is then cured with the planar template and composition in contact with each other, and the planar template is separated from the cured composition.

The planarization layer is thereby formed on the substrate. Unlike typical planarization methods using SOC sacrificial layers, this planarization apparatus is not affected by the unevenness of the substrate's patterned surface and is thus expected to improve the planarization accuracy compared to the existing methods.

The planarization apparatus 100 in FIG. 1 can be implemented by a molding apparatus that molds composition on the substrate 1 using a plate (superstrate) 9 that is a pressing member. The planarization apparatus 100 cures the composition with the material on the substrate 1 and the plate 9 in contact with each other, and separates the plate 9 from the cured composition, whereby a planarization layer of the material is formed on the substrate 1.

The substrate 1 is a semiconductor, insulator, or metal substrate, and may have a circular shape like a silicon wafer and a quartz wafer, or a rectangular shape like a (mother) glass for flat panel display (FPD). The material of the substrate 1 may be a monocrystalline silicon wafer, but this is not restrictive. Examples of the substrate material may include silicon, germanium, diamond, silicon carbide, silicon germanium, gallium nitride, gallium arsenide, indium arsenide, cadmium telluride, and other elemental or compound semiconductors. Other examples of the material of the substrate 1 may include inorganic insulators such as silicon oxide, silicon nitride, aluminum oxide, and aluminum nitride. Other examples of the material of the substrate 1 may include organic insulators such as polyimide, polyamide, and polycarbonate. The substrate 1 may be made of aluminum, titanium-tungsten alloy, aluminum-silicon alloy, or aluminum-copper-silicon alloy. In short, the substrate 1 may be made of any one or more materials selected from the foregoing materials and the like. At least one layer of semiconductor, insulator, or metal film may be formed on the surface of the substrate 1, and the film surface may be flat or patterned.

An adhesion layer may be formed on the substrate surface by surface treatments such as silane coupling treatment, silazane treatment, and organic thin film deposition, and the resulting substrate with improved adhesion with composition may be used. The substrate 1 typically has, but is not limited to, a 300-mm-diameter circular shape.

The plate 9 may be made of an optically transparent material in view of the light irradiation process. Examples of such material include optically transparent inorganic materials such as glass and quartz, and optically transparent organic materials such as polymethyl methacrylate (PMMA) and polycarbonate resin. The plate 9 may be a rigid plate or a flexible film. The surface of the plate 9 to contact the composition is flat. The plate 9 can have, but is not limited to, a circular shape with a diameter greater than 300 mm and less than 500 mm. The suitable thickness of the plate 9 is, but not limited to, 0.25 mm or more and less than 2 mm. If the composition is not a photocuring material but a thermosetting one, the plate 9 does not need to be transparent and may be made of any material having the foregoing properties.

The composition is a precursor that cures to form at least part of a planarization film, and is a curable composition that is curable by light or thermal energy. The curable composition that is curable by light or thermal energy may be a photocurable composition that cures when irradiated with light, a thermosetting composition that cures when heated, or a photo-thermosetting component that cures when exposed to both light and thermal energy. Examples of the photocurable composition include ultraviolet (UV)-curable liquids. Typically, monomers such as acrylates and methacrylates are used as UV-curable liquids. The curable composition may be referred to as moldable material. Moldable material may hereinafter be referred to simply as “material”.

As illustrated in FIG. 1, the planarization apparatus 100 includes a substrate chuck 2, a substrate stage 3, a base platen 4, support columns 5, a top plate 6, guide bars 7, support columns 8, a plate chuck 11, a head 12, and an alignment stage 13. The planarization apparatus 100 further includes a pressure adjustment unit 15, a supply unit 17, a substrate transport unit 18, alignment scopes 19, a light source 20, a stage drive unit 21, a plate transport unit 22, a cleaning unit 23, an input unit 24, and a control unit 200. The substrate chuck 2 and the substrate stage 3 can hold and move the substrate 1. The plate chuck 11 and the head 12 can hold and move the plate 9.

The substrate 1 is carried into the planarization apparatus 100 from outside by the substrate transport unit 18 including a transport hand, and held by the substrate chuck 2. The substrate stage 3 is supported by the base platen 4, and driven in the X and Y directions to position the substrate 1 held by the substrate chuck 2 to a predetermined position. The stage drive unit 21 includes linear motors or air cylinders, for example, and drives the substrate stage 3 at least in the X and Y direction. The stage drive unit 21 may have a function of driving the substrate stage 3 in three or more axial directions (for example, six axial directions). The stage drive unit 21 includes a rotation mechanism, and can drive the substrate chuck 2 or the substrate stage 3 to rotate in the θZ direction.

The plate 9 that is the pressing member is carried into the planarization apparatus 100 from outside by the plate transport unit 22 including a transport hand, and held by the plate chuck 11. The plate 9 has a circular or rectangular outer shape, for example, and has a first surface including a flat surface 10 to contact material placed on the substrate 1, and a second surface opposite to the first surface. In the present embodiment, the flat surface 10 has the same size as or is greater than the substrate 1. The plate chuck 11 is supported by the head 12, and has a function of correcting the position of the plate 9 in the θZ direction (tilt about the Z-axis). The plate chuck 11 and the head 12 each have an opening that allows light (ultraviolet rays) emitted from the light source 20 via a collimator lens to pass through. The plate chuck 11 functions as a holding unit that mechanically holds the plate 9. For example, the plate chuck 11 holds the plate 9 by attracting the second surface of the plate 9 with the second surface upward. The head 12 mechanically holds the plate chuck 11. The plate chuck 11 and the head 12 constitute a formation unit 50 that performs planarization film formation processing. The head 12 includes a drive mechanism (not illustrated) for adjusting the distance between the substrate 1 and the plate 9 when the plate 9 is brought into contact with the material on the substrate 1 and separated from the material, and moves the plate 9 in the Z direction. For example, the drive mechanism of the head 12 can include an actuator such as a linear motor, an air cylinder, and a voice coil motor. A load cell for measuring the pressing force (imprint force) of the plate 9 against the material on the substrate 1 may be disposed on the plate chuck 11 or the head 12. A plate deformation mechanism (plate deformation unit) includes a sealing member 14 that makes a spatial region A, which is formed by the internal space of the plate chuck 11 and the internal space enclosed by the plate 9 and the sealing member 14, into a sealed space. The plate deformation mechanism also includes the pressure adjustment unit 15, which is located outside the plate chuck 11 and adjusts the pressure inside the spatial region A. The sealing member 14 is made of an optically transparent flat member such as quartz glass, and includes a connection port (not illustrated) for piping 16 connected to the pressure adjustment unit 15. The pressure adjustment unit 15 can increase the amount of deformation of the plate 9 convex toward the substrate 1 by increasing the pressure of the spatial region A. The pressure adjustment unit 15 can also reduce the amount of deformation of the plate 9 convex toward the substrate 1 by reducing the pressure of the spatial region A. The support columns 5 for supporting the top plate 6 are disposed on the base platen 4. The guide bars 7 are suspended from the top plate 6, passed through the alignment stage 13, and fixed to the head 12. The alignment stage 13 is suspended from the top plate 6 via the support columns 8. The guide bars 7 run through the alignment stage 13. A height measurement system (not illustrated) for measuring the height (flatness) of the substrate 1 held by the substrate chuck 2 using an oblique incidence image displacement method, for example, is disposed on the alignment stage 13.

The alignment scopes 19 include optical systems and imaging systems for observing reference marks provided on the substrate stage 3 and alignment marks provided on the plate 9. If the plate 9 has no alignment mark, the alignment scopes 19 may be omitted. The alignment scopes 19 are used for alignment purposes to measure the relative position between the reference marks on the substrate stage 3 and the alignment marks on the plate 9 and correct their positional deviation.

The supply unit 17 includes a dispenser that includes discharge ports (nozzles) for discharging uncured material to the substrate 1, and supplies (applies) the material onto the substrate 1. The supply unit 17 employs a piezo jet method or micro solenoid method, for example, and can supply small volumes of material, like 1 pL or so, onto the substrate 1 during scan driving. The number of discharge ports of the supply unit 17 is not limited in particular, and may be one (single nozzle) or multiple (for example, 100 or more). Multiple nozzles may constitute a single-or multiple-row linear nozzle array. In particular, dispensers known as inkjet heads can suitably apply liquid material to the substrate in small droplets. A piezo inkjet head including at least one piezoelectric discharge energy generator for each discharge port is more suitable, in particular, since the volume of the discharged droplets can be changed.

The cleaning unit 23 cleans the plate 9 with the plate 9 held on the plate chuck 11. The cleaning unit 23 removes material adhering to the plate 9, or the flat surface 10 in particular, when the plate 9 is separated from the cured material on the substrate 1. For example, the cleaning unit 23 may wipe off the material adhering to the plate 9, or remove the material adhering to the plate 9 using UV irradiation, static elimination, wet cleaning, dry plasma cleaning, or the like.

The control unit 200 is constituted by a computer device including a central processing unit (CPU) and memory, and controls the entire planarization apparatus 100. The control unit 200 functions as a processing unit that controls the components of the planarization apparatus 100 in a comprehensive manner to perform planarization processing. As employed herein, the planarization processing refers to processing for planarizing the material on the substrate 1 by bringing the flat surface 10 of the plate 9 into contact with the material so that the flat surface 10 follows the surface shape of the substrate 1. The planarization processing is typically performed in units of lots, i.e., on each of a plurality of substrates included in the same lot.

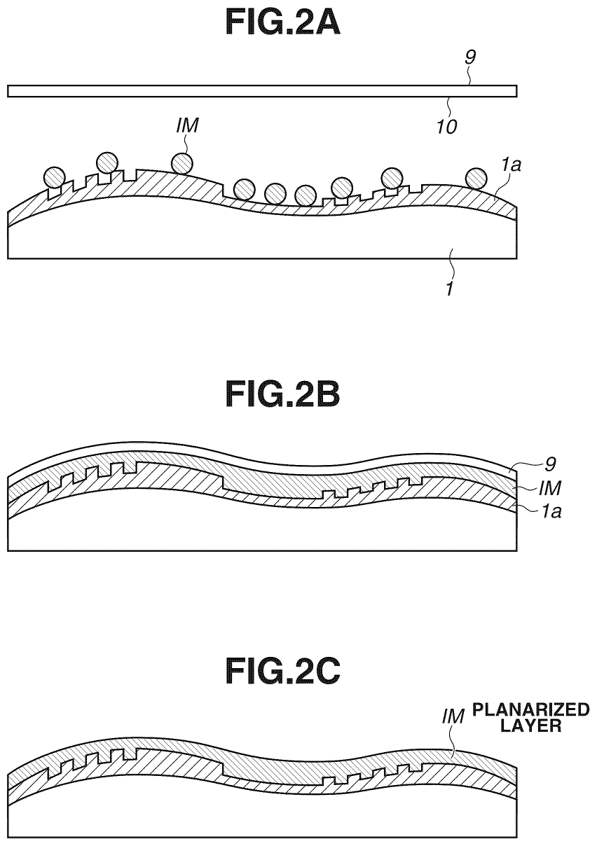

Next, the planarization processing will be described with reference to FIGS. 2A, 2B, and 2C. Initially, the supply unit 17 supplies material IM to the substrate 1 on which an underlying pattern 1a is formed. FIG. 2A illustrates a state where the material IM is placed on the substrate 1 before the plate 9 is brought into contact. Next, as illustrated in FIG. 2B, the material IM on the substrate 1 and the flat surface 10 of the plate 9 are brought into contact. The plate 9 presses the material IM, whereby the material IM is spread over the entire surface of the substrate 1. FIG. 2B illustrates the state where the entire flat surface 10 of the plate 9 contacts the material IM on the substrate 1, and the flat surface 10 of the plate 9 follows the surface shape of the substrate 1. In the state illustrated in FIG. 2B, the light source 20 then irradiates the material IM on the substrate 1 with light via the plate 9, whereby the material IM is cured. The plate 9 is then separated from the cured material IM on the substrate 1. A layer (planarization layer) of the material IM having a uniform thickness is thereby formed over the entire surface of the substrate 1. FIG. 2C illustrates the state where the planarization layer of the material IM is formed on the substrate 1. In the following description, the contact (close contact) and separation of the flat surface 10 of the plate 9 and the material IM on the substrate 1 will be referred to simply as the contact (close contact) and separation of the plate 9 and the material IM on the substrate 1, respectively. Moreover, the material IM in the state of being supplied onto the substrate 1 may hereinafter be referred to as a precursor, and the cured material IM as a film.

Next, a method for manufacturing an article (such as a semiconductor device, a liquid crystal display device, a color filter, and micro-electromechanical systems [MEMS]) using the planarization apparatus 100 will be described. This manufacturing method includes the steps of planarizing a composition placed on a substrate (such as a wafer and a glass substrate) by bringing the composition and a mold into contact with each other, curing the composition, and separating the composition and the mold, using the foregoing planarization apparatus 100. A planarization film is thereby formed on the substrate. The substrate on which the planarization film is formed is then subjected to processing such as pattern formation (patterning) using a lithographic apparatus, and the processed substrate is processed in other conventional processing or machining steps to manufacture the article. The other conventional steps include etching, resist removal, dicing, bonding, and packaging. With this manufacturing method, articles of higher quality than heretofore can be manufactured.

A method for manufacturing a semiconductor device will now be described by using a semiconductor device as a specific example of the article. The semiconductor device is a photoelectric conversion sensor, for example. The method for manufacturing a semiconductor device according to the present embodiment is an application of the planarization method described with reference to FIGS. 1, 2A, 2B, and 2C to a configuration including a plurality of chips arranged on a substrate.

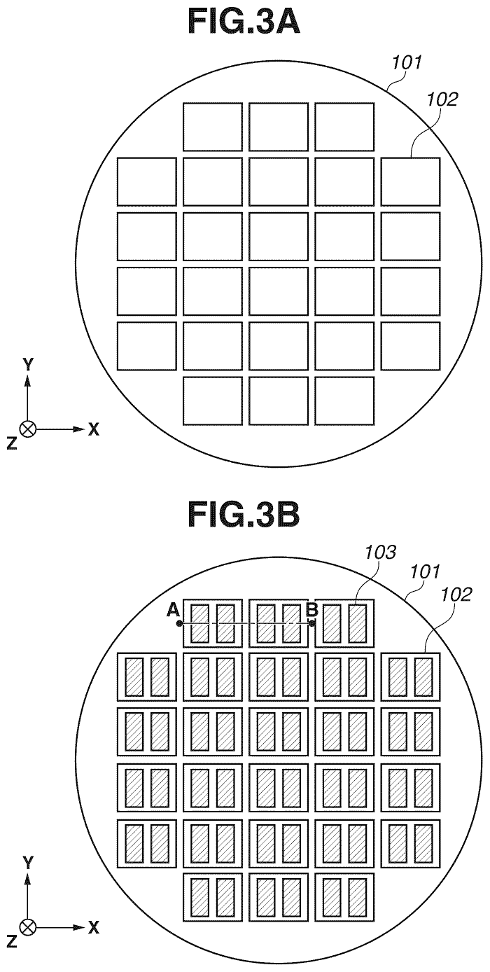

FIGS. 3A and 3B are schematic plan views for describing the method for manufacturing a semiconductor device according to the present embodiment. FIG. 3A illustrates a step of preparing a substrate 101 (first substrate) including parts 102. FIG. 3A is a diagram illustrating the planar layout of the substrate 101. The substrate 101 has a circular shape, and a plurality of parts 102 is arranged thereon. The substrate 101 may include a semiconductor wafer and wiring structures formed thereon. The substrate 101 is a semiconductor substrate including a silicon monocrystalline substrate as its semiconductor wafer, for example. The parts 102 may be semiconductor elements that include portions formed in the semiconductor wafer and portions formed by the wiring structure, for example. The substrate 101 and the parts 102 are formed by a typical semiconductor device manufacturing method.

FIG. 3B illustrates a step of preparing a member where chips 103 are further arranged on the configuration of FIG. 3A. In the following steps, the substrate 101 and the chips 103 may be referred to correctively as a member. FIG. 3B is a diagram illustrating the planar layout of the substrate 101 on which the chips 103 are arranged. This step may be implemented, for example, by a method of bonding the conductor patterns of the substrate 101 and the chips 103 to each other. The present embodiment demonstrates an example where two chips 103 are disposed on each single part 102. The chips 103 can include circuits for operating the part 102 and circuits for processing signals output from the part 102. The number of chips disposed on a single part 102 is not limited to two. A plurality of chips 103 having the same functions may be disposed on the part 102. A plurality of chips 103 having respective different functions may be disposed on the part 102. Examples of the chips 103 include semiconductor chips.

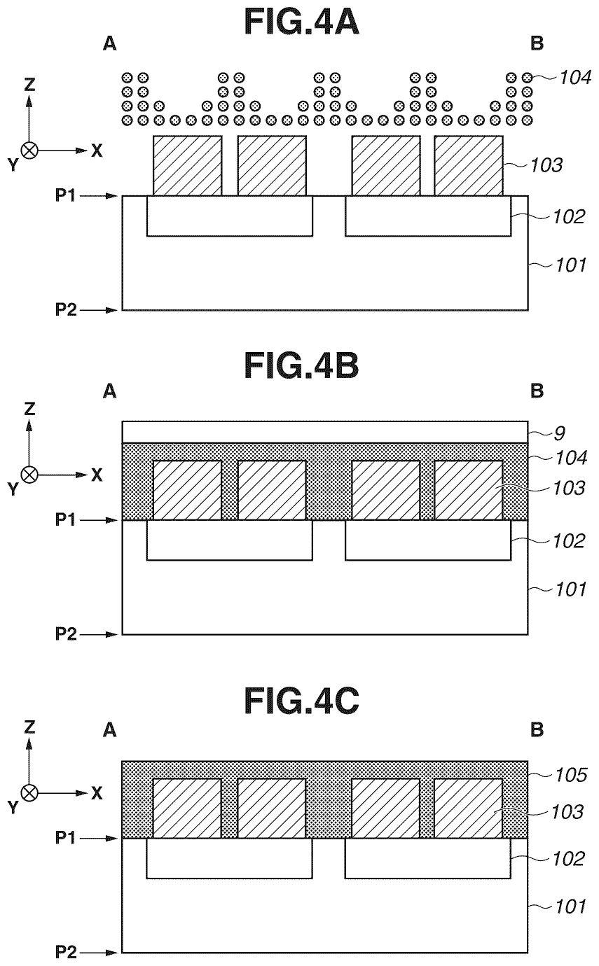

Next, a step of burying the chips 103 arranged on the substrate 101 is performed. FIGS. 4A, 4B, and 4C are schematic sectional views taken along line A-B of FIG. 3B. The step of burying the chips 103 will be described. The substrate 101 has a first surface P1 and a second surface P2 opposed to the first surface P1. As employed herein, the first surface P1 may be referred to as the top surface of the substrate 101, and the second surface P2 the bottom surface of the substrate 101.

The parts 102 may include photoelectric conversion elements that convert light into electric charges, for example. Typically, each part 102 includes a plurality of photoelectric conversion elements that is arranged in an array with a plurality of rows and a plurality of columns. The photoelectric conversion elements generate charges based on light incident from the second surface P2. Not-illustrated transfer transistors transfer the charges from the photoelectric conversion elements to not-illustrated floating diffusion regions. Output circuits including not-illustrated amplification transistors output signals based on the amounts of charges transferred to the floating diffusion regions to not-illustrated column circuits. The column circuits are disposed on the chips 103, for example, and perform various types of processing including analog-to-digital (AD) conversion processing for converting the input signals into digital signals and processing for reducing noise component. Digital signals are sequentially read from the plurality of column circuits. The semiconductor device including the photoelectric conversion elements can thus generate signals based on the light incident on the photoelectric conversion elements.

FIG. 4A illustrates the step of applying a liquid precursor 104 (the foregoing material IM) onto the substrate 101 on which the chips 103 are arranged. The precursor 104 is applied in predetermined application amounts so that the precursor 104 is applied less onto the chips 103 and more onto the other portions. The liquid precursor 104 may be an energy curable resin precursor or an SOC precursor. Examples of the energy curable resin precursor may include photocurable compositions.

The uncured material IM is applied onto the chips 103 formed in advance, using an inkjet head equipped with piezoelectric elements serving as discharge actuators. Specifically, the application step is implemented by applying droplets onto the chips 103 N times per unit area (N is a natural number) and onto the other flat surface of the substrate 101 (between the plurality of chips 103) (N+1) times or more per unit area. The numbers of droplets to be applied can be determined based on the arrangement pattern of the chips 103. Specifically, droplets are applied by changing the relative position of the discharge ports and the substrate 101 based on a drawing map where the numbers (or amounts) of droplets to be applied onto the substrate 101 and the application positions within the first surface P1 are determined based on arrangement pattern data on the chips 103. The amount of application can be changed not only by changing the number of droplets of the liquid precursor 104 but also by changing the droplet size. Both may be adjusted.

In FIG. 4B, the flat surface 10 of the plate 9 is pressed against the precursor 104, and the liquid is cured. This step improves the flatness over the chips 103. The precursor 104 may be cured by irradiating the precursor 104 with light through the plate 9. For example, an exposure apparatus may be used as the curing apparatus. An ArF immersion exposure apparatus, an ArF dry exposure apparatus, or a KrF exposure apparatus may be used. The exposure amount may also be adjusted depending on the arrangement pattern of the chips 103.

As illustrated in FIG. 4C, the plate 9 is then separated from the cured precursor 104. A first film 105 having a highly flat top surface is formed through such planarization processing. Here, part of the first film 105 located over the chips 103 may be removed.

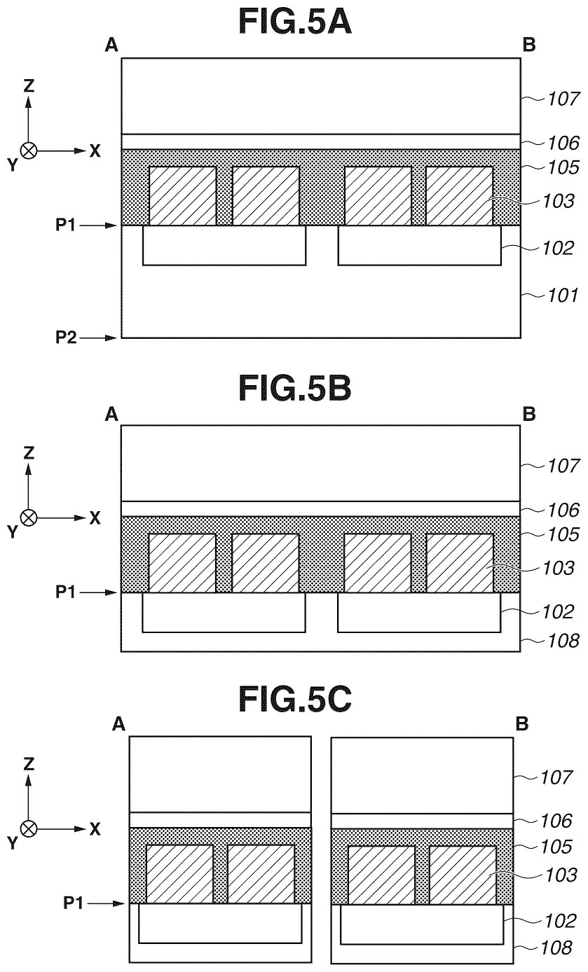

In FIG. 5A, the substrate 101 having the first film 105 is then integrated with a support substrate 107 (second substrate). Specifically, an adhesive layer 106 is applied onto the first film 105, and the support substrate 107 is adhesively bonded thereto. Alternatively, the material of the portion of the first film 105 forming the bonding interface and the material of the portion of the support substrate 107 forming the bonding interface may be appropriately selected to cause bonding (for example, covalent bonding or the like) between the materials at the bonding interface.

In FIG. 5B, the substrate 101 is thinned into a substrate 108 (third substrate). The thinning can be performed using techniques such as etching, mechanical polishing, and CMP. If the substrate 101 is a Silicon-on-Insulator (SOI) substrate or the like, the thinning can be performed by water jetting. Such processing can reduce the semiconductor layer of the substrate 101 in thickness, whereby at least one of effects including miniaturization and improved heat dissipation can be obtained.

As illustrated in FIG. 5C, the entire member is then diced into a desired number of pieces, whereby semiconductor devices are completed.

As described above, the method for manufacturing a semiconductor device according to the present embodiment can provide a technique advantageous to a method for manufacturing a semiconductor device where a plurality of chips is disposed on a substrate. In the present embodiment, the flatness over the plurality of chips 103 and the portions between the plurality of chips 103 improves. Since the flatness of the bonding interface of the first film 105 with the support substrate 107 improves, the bonding strength between the support substrate 107 and the first film 105 improves.

In the present embodiment, when applying the material IM, the inkjet head is controlled so that droplets are discharged less onto the chips 103 than onto the portions other than where the chips 103 are located. However, this mode is not restrictive. For example, the material IM is applied so that droplets are uniformly applied onto the chips 103 and onto the portions other than where the chips 103 are located. The flat plate 9 is then brought into contact with the material IM. Even with such a method, the amount of material IM on the chips 103 can be made smaller than that of material IM on the portions other than where the chips 103 are located. Such a technique is also covered by the step of applying the precursor 104 so that the amount of application onto the chips 103 is smaller than onto the other portions.

In FIG. 4B, the support substrate 107 illustrated in FIG. 5A may be used instead of the plate 9. In such a case, the liquid precursor 104 (material IM) can be a thermosetting composition. As illustrated in FIG. 5B, the substrate 101 is then thinned into the substrate 108 (third substrate). As illustrated in FIG. 5C, the entire member is then diced into a desired number of pieces, whereby semiconductor devices are completed. This manufacturing method can eliminate the step of separating the plate 9 from the cured precursor 104 (the step illustrated FIG. 4C) and the step of applying the adhesive layer 106 (part of the step illustrated in FIG. 5A).

### Second Embodiment

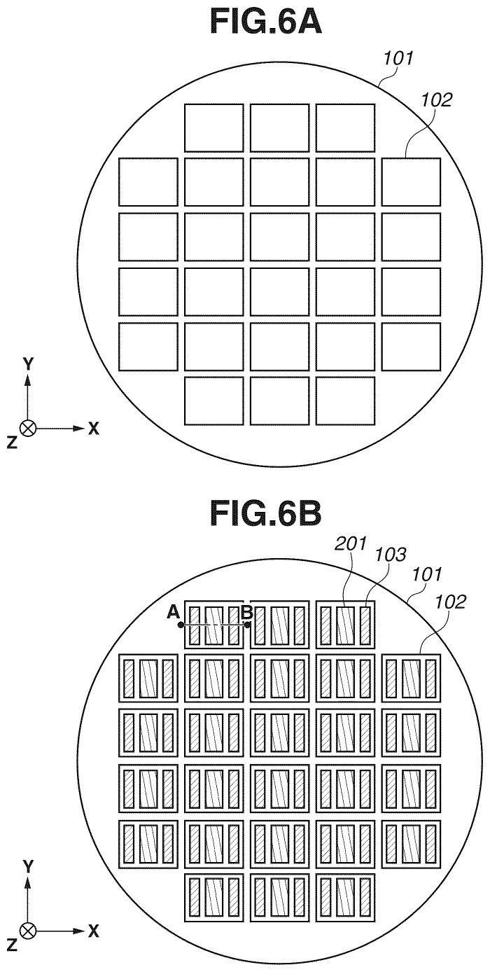

A method for manufacturing a semiconductor device according to the present embodiment will be described. FIGS. 6A and 6B are schematic diagrams for describing the method for manufacturing a semiconductor device according to the second embodiment. The present embodiment differs from the first embodiment in that a chip having a different size from the chips 103 is also disposed on the part 102 in addition to the chips 103. Hereinafter, a detailed description will be omitted of configurations and steps similar to those of the first embodiment.

FIGS. 6A and 6B are schematic plan views for describing the method for manufacturing a semiconductor device according to the present embodiment. FIG. 6A illustrates the step of preparing the substrate 101 (first substrate) including the parts 102. FIG. 6A is a diagram illustrating the planar layout of the substrate 101.

FIG. 6B illustrates the step of preparing a member where the chips 103 and chips 201 are further arranged on the configuration of FIG. 6A. In the following steps, the substrate 101, the chips 103, and the chips 201 may be referred to collectively as a member. FIG. 6B is a diagram illustrating the planar layout of the substrate 101 on which the chips 103 and 201 are arranged. The present embodiment describes an example where two chips 103 and one chip 201 having a different size from the chips 103 are disposed on each single part 102. The chip 201 may include circuits for operating the part 102 and circuits for processing signals output from the part 102. The chip 201 is a semiconductor chip, for example.

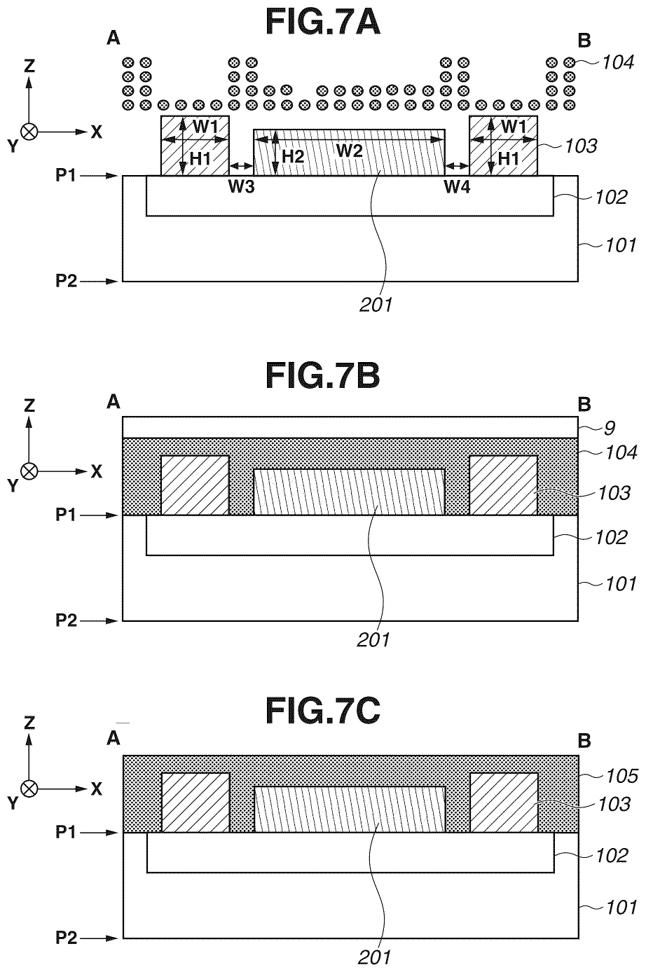

FIGS. 7A, 7B, and 7C are schematic sectional views taken along line A-B of FIG. 6B. A step of burying the chips 103 and the chip 201 will now be described. The chips 103 have a height H1 greater than the height H2 of the chip 201. The chips 103 have a width W1 smaller than the width W2 of the chip 201. A distance W3 between one of the chips 103 and the chip 201 is substantially the same as a distance W4 between the other chip 103 and the chip 201. The heights H1 and H2 can be 1 to 30 μm or so, for example. The widths W1 and W2 can be 1 to 10 mm or so, for example.

FIG. 7A illustrates a step of applying the liquid precursor 104 (the foregoing material IM) onto the substrate 101 on which the chips 103 and 201 are disposed. The precursor 104 is applied in predetermined application amounts so that the precursor 104 is applied onto the chips 103 by a first amount, onto the chip 201 by a second amount, and onto the other portions by a third amount. Examples of the other portions include the regions between the chips 103 and the chip 201. The first amount is less than the second amount, and the second amount is less than the third amount.

The liquid precursor 104 may be an energy curable resin precursor or an SOC precursor. Examples of the energy curable resin may include photocurable compositions.

The uncured material IM is applied onto the chips 103 and 201 formed in advance, using an inkjet head equipped with piezoelectric elements serving as discharge actuators. Specifically, droplets are applied onto the chips 103 N times per unit area (N is a natural number), and onto the chip 201 M times per unit area (M is a natural number greater than N). Moreover, droplets are applied onto the other flat surface of the substrate 101 (between the chips 103 and the chip 201) L times or more per unit area (L is a natural number greater than M). The numbers of droplets to be applied can be determined based on the arrangement pattern of the chips 103 and 201. Specifically, droplets are applied by changing the relative position of the discharge ports and the substrate 101 based on a drawing map where the numbers (or amounts) of droplets to be applied onto the substrate 101 and the application positions within the first surface P1 are determined based on arrangement pattern data on the chips 103 and 201. The amount of application can be changed not only by changing the number of droplets of the liquid precursor 104 but also by changing the droplet size. Both may be adjusted.

In FIG. 7B, the flat surface 10 of the plate 9 is pressed against the precursor 104, and the liquid is cured. This step improves the flatness over the chips 103 and 201. The precursor 104 may be cured by irradiating the precursor 104 with light through the plate 9. For example, an exposure apparatus may be used as the curing apparatus. An ArF immersion exposure apparatus, an ArF dry exposure apparatus, or a KrF exposure apparatus may be used. The exposure amount may be adjusted depending on the arrangement pattern of the chips 103 and 201.

As illustrated in FIG. 7C, the plate 9 is then separated from the cured precursor 104. A first film 105 having a highly flat top surface is formed through such planarization processing. Here, part of the first film 105 located over the chips 103 and 201 may be removed.

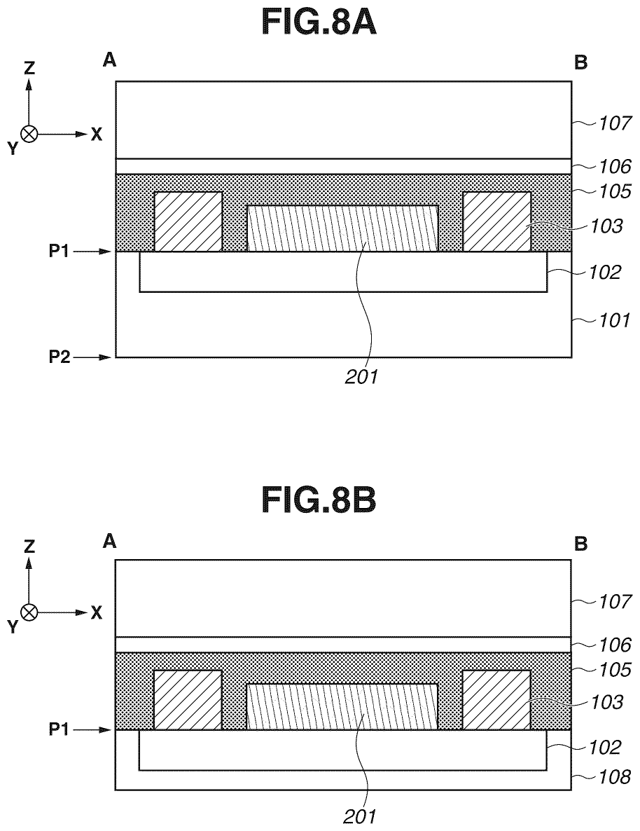

Next, in FIG. 8A, the substrate 101 having the first film 105 is integrated with a support substrate 107 (second substrate). Specifically, an adhesive layer 106 is applied onto the first film 105, and the support substrate 107 is adhesively bonded thereto. Alternatively, the material of the portion of the first film 105 forming the bonding interface and the material of the portion of the support substrate 107 forming the bonding interface may be appropriately selected to cause bonding (for example, covalent bonding or the like) between the materials at the bonding interface.

In FIG. 8B, the substrate 101 is thinned into a substrate 108 (third substrate). The thinning can be performed using techniques such as etching, mechanical polishing, and CMP. If the substrate 101 is a SOI substrate or the like, the thinning can be performed by water jetting. Such processing can reduce the semiconductor layer of the substrate 101 in thickness, whereby at least one of effects including miniaturization and improved heat dissipation can be obtained.

The entire member is then diced into a desired number of pieces, whereby semiconductor devices are completed.

As described above, the method for manufacturing a semiconductor device according to the present embodiment can provide a technique advantageous to a method for manufacturing a semiconductor device where a plurality of chips is disposed on a substrate. In the present embodiment, the flatness over the plurality of chips 103, the chip 201, and the portions between the plurality of chips 103 and 201 improves. In other words, even if a plurality of chips with different heights and widths is disposed on the part 102, the first film 105 with high flatness can be formed by adjusting the amount of the precursor 104. Since the flatness of the bonding interface of the first film 105 with the support substrate 107 improves, the bonding strength between the support substrate 107 and the first film 105 improves.

The number of chips disposed on a single part 102, the widths of the chips, the heights of the chips, and the chip-to-chip distances are not limited to those of FIGS. 6A and 6B. The amount of application of the precursor 104 can be determined based on the number of chips, the widths of the chips, the heights of the chips, and the chip-to-chip distances. For example, the distance W3 and the distance W4 may be different. Even in such a case, the first film 105 with high flatness can be formed.

In the present embodiment, when applying the material IM, the inkjet head is controlled so that different amounts of droplets are discharged onto the chips 103, the chip 201, and the other portions. However, this mode is not restrictive. For example, the material IM is applied so that droplets are uniformly applied onto the chips 103, the chip 201, and the portions other than where the chips 103 and 201 are located. The flat plate 9 is then brought into contact with the material IM. Even with such a method, the material IM can be applied onto the chips 103 by a first amount, onto the chip 201 by a second amount, and onto the portions other than the chips 103 and 201 by a third amount. Such a technique is also covered by the step of applying the precursor 104 so that the amount of application onto the chips 103 and 201 is smaller than onto the other portions.

In FIG. 7B, the support substrate 107 illustrated in FIG. 8A may be used instead of the plate 9. In such a case, the liquid precursor 104 (material IM) can be a thermosetting composition. As illustrated in FIG. 8B, the substrate 101 is then thinned into the substrate 108 (third substrate). The entire member is then diced into a desired number of pieces, whereby semiconductor devices are completed. This manufacturing method can eliminate the step of separating the plate 9 from the cured precursor 104 (the step illustrated FIG. 7C) and the step of applying the adhesive layer 106 (part of the step illustrated in FIG. 8A).

### Third Embodiment

The present embodiment describes application examples where semiconductor devices manufactured by the manufacturing methods according to the first and second embodiments are used. A semiconductor device 910 is a photoelectric conversion sensor, for example.

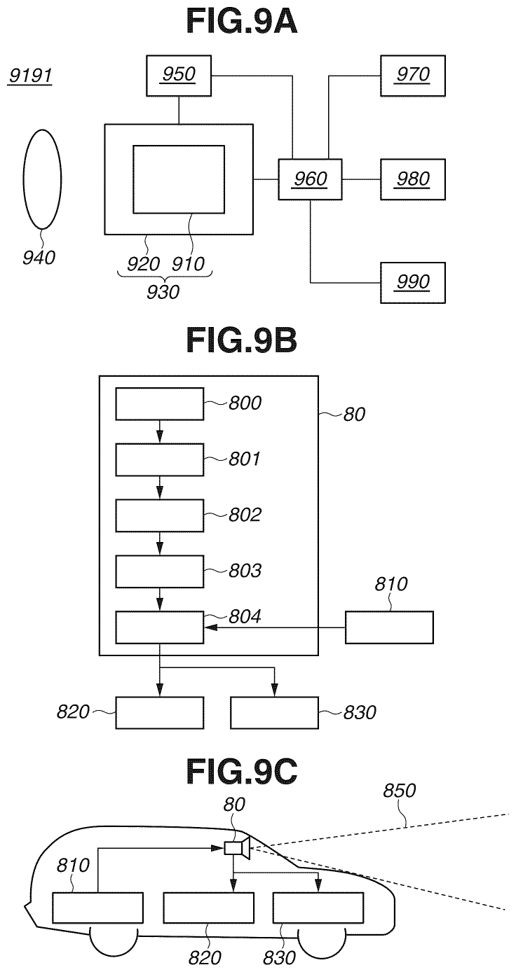

FIG. 9A is a schematic diagram for describing equipment 9191 that is an application example. The equipment 9191 includes a semiconductor apparatus 930. The semiconductor apparatus 930 includes the semiconductor device 910 and a package 920 that accommodates the semiconductor device 910. The semiconductor device 910 may be manufactured by manufacturing methods according to other embodiments. The package 920 may include a base to which the semiconductor device 910 is fixed, and a glass or other lid opposed to the semiconductor device 910. The package 920 may further include bonding members such as bonding wires and bumps that connect terminals provided on the base and terminals provided on the semiconductor device 910.

The equipment 9191 may include at least one of the following: an optical apparatus 940, a control apparatus 950, a processing apparatus 960, a display apparatus 970, a storage apparatus 980, and a mechanical apparatus 990. The optical apparatus 940 is compatible with the semiconductor apparatus 930. The optical apparatus 940 is a lens, shutter, mirror, or the like, for example, and includes an optical system for guiding light to the semiconductor apparatus 930. The control apparatus 950 controls the semiconductor apparatus 930. The control apparatus 950 is a semiconductor apparatus such as an application-specific integrated circuit (ASIC).

The processing apparatus 960 processes signals output from the semiconductor apparatus 930. The processing apparatus 960 is a semiconductor apparatus for constituting an analog front end (AFE) or digital front end (DFE). Examples include a CPU and an ASIC. The display apparatus 970 is an electroluminescence (EL) display apparatus or a liquid crystal display apparatus that displays information (images) obtained by the semiconductor apparatus 930. The storage apparatus 980 is a magnetic device or semiconductor device that stores information (images) obtained by the semiconductor apparatus 930. The storage apparatus 980 is a volatile memory such as a static random access memory (SRAM) and a dynamic random access memory (DRAM), or a nonvolatile memory such as a flash memory and a hard disk drive.

The mechanical apparatus 990 includes a movable unit or propelling unit such as a motor and an engine. The equipment 9191 displays signals output from the semiconductor apparatus 930 on the display apparatus 970, or transmits the signals to outside using a communication apparatus (not illustrated) included in the equipment 9191. For that purpose, the equipment 9191 can include the storage apparatus 980 and the processing apparatus 960 aside from a storage circuit and a calculation circuit included in the semiconductor apparatus 930. The mechanical apparatus 990 may be controlled based on the signals output from the semiconductor apparatus 930.

The equipment 9191 is suitable for electronic equipment such as information terminals having an imaging function (for example, smartphones and wearable terminals) and cameras (for example, interchangeable-lens cameras, compact cameras, video cameras, and surveillance cameras). The mechanical apparatus 990 in a camara can drive components of the optical apparatus 940 for zooming, focusing, and shutter operations. Alternatively, the mechanical apparatus 990 in a camera can move the semiconductor apparatus 930 for image stabilization operation.

The equipment 9191 may be transportation equipment such as vehicles, ships, and aircraft. The mechanism apparatus 990 in transportation equipment can be used as a moving apparatus. The equipment 9191 as transportation equipment is suitable for equipment that transports the semiconductor apparatus 930, or equipment that assists and/or automates operation (driving) using the imaging function. The processing apparatus 960 for assisting and/or automating operation (driving) can perform processing for operating the mechanical apparatus 990 serving as a moving apparatus based on information obtained by the semiconductor apparatus 930. Alternatively, the equipment 9191 may be medical equipment such as endoscopes, measurement equipment such as distance sensors, analytic equipment such as electronic microscopes, office equipment such as copying machines, or industrial equipment such as robots.

According to the embodiment described above, favorable pixel characteristics can be obtained. The value of the semiconductor apparatus 930 can thus be enhanced. As employed herein, enhancing the value includes at least one of the following: adding functions, improving performance, improving characteristics, improving reliability, improving manufacturing yield, reducing environmental load, cost reduction, miniaturization, and weight reduction.

The use of the semiconductor apparatus 930 according to the present embodiment for the equipment 9191 can thus improve the value of the equipment 9191 as well. For example, when the semiconductor apparatus 930 is mounted on transportation equipment, excellent performance can be obtained in capturing images outside the transportation equipment or measuring the external environment. In manufacturing and selling transportation equipment, deciding to incorporate the semiconductor apparatus 930 according to the present embodiment in the transportation equipment is advantageous for improving the performance of the transportation equipment itself. In particular, the semiconductor apparatus 930 is suitable for transportation equipment that performs driving assistance and/or automated driving using information obtained by semiconductor apparatuses.

Next, a moving body will be described as another application example. FIG. 9B illustrates an example of a photoelectric conversion system related to an in-vehicle camera. A photoelectric conversion system 80 includes a semiconductor device 800. The semiconductor device 800 is a photoelectric conversion device (imaging device), for example. The photoelectric conversion system 80 includes an image processing unit 801 and a parallax acquisition unit 802. The image processing unit 801 performs image processing on a plurality of pieces of image data acquired by the semiconductor device 800. The parallax acquisition unit 802 calculates parallax (phase difference between parallax images) from the plurality of pieces of data acquired by the photoelectric conversion system 80.

Here, the photoelectric conversion system 80 may include a not-illustrated optical system that guides light to the semiconductor device 800, such as a lens, shutter, and mirror. Pixels of the semiconductor device 800 may include a plurality of photoelectric conversion units substantially conjugate with the pupil of the optical system. For example, a plurality of photoelectric conversion units substantially conjugate with the pupil is provided for a single microlens. The plurality of photoelectric conversion units receives light beams transmitted through respective different positions of the pupil of the optical system, whereby the semiconductor device 800 outputs image data corresponding to the light beams transmitted through different positions. The parallax acquisition unit 802 then may calculate parallax using the output image data. The photoelectric conversion system 80 also includes a distance acquisition unit 803 that calculates the distance to an object based on the calculated parallax, and a collision determination unit 804 that determines whether there is a possibility of collision based on the calculated distance. The parallax acquisition unit 802 and the distance acquisition unit 803 are examples of a distance information acquisition unit that acquires distance information about an object. In other words, distance information is information about parallax, defocus amount, distance to an object, etc. The collision determination unit 804 may determine the possibility of collision using one of such pieces of distance information. The distance information may be acquired using Time of Flight (ToF). The distance information acquisition unit may be implemented by dedicatedly designed hardware or by a software module. A field programmable gate array (FPGA), ASIC, or the like may be used for implementation. A combination of these may be used for implementation.

The photoelectric conversion system 80 is connected to a vehicle information acquisition apparatus 810, and can acquire vehicle information such as vehicle speed, yaw rate, and steering angle. The photoelectric conversion system 80 is also connected to an electric control unit (ECU) 820, which is a control apparatus that outputs control signals for causing the vehicle to produce braking force based on the determination result of the collision determination unit 804. The photoelectric conversion system 80 is also connected to an alarm apparatus 830 that issues an alarm to the driver based on the determination result of the collision determination unit 804. For example, if the determination result of the collision determination unit 804 indicates a high possibility of collision, the ECU 820 performs vehicle control to avoid the collision or reduce damage by applying brakes, releasing the accelerator, suppressing engine output, etc. The alarm apparatus 830 warns the user by sounding an alarm, displaying warning information on the screen of a car navigation system, vibrating the seatbelt or the steering wheel, etc.

In the present embodiment, the photoelectric conversion system 80 captures images around the vehicle, such as images in front or behind. FIG. 9C illustrates the photoelectric conversion system 80 in the case of capturing images in front of the vehicle (imaging range 850). The vehicle information acquisition apparatus 810 sends instructions to the photoelectric conversion system 80 or the semiconductor device 800. Such a configuration can further improve the accuracy of distance measurement.

While an example of exercising control to avoid collision with other vehicles has been described above, the photoelectric conversion system 80 is also applicable to automated driving control to follow another vehicle, automated driving control to stay in the lane, or the like. Moreover, the photoelectric conversion system 80 is not limited to vehicles such as automobiles, either, and can be applied to a moving body (moving apparatus) such as a ship, aircraft, and industrial robot. This moving body includes either one or both of a driving force generation unit that generates driving force mainly used to move the driving body and a rotating body mainly used to move the driving body. The driving force generation unit may be an engine, motor, or the like. The rotating body may be a tire, wheel, ship screw, propeller, or the like. The photoelectric conversion system 80 is not limited to moving bodies, either, and can be widely applied to equipment that uses object recognition, such as intelligent transportation system (ITS).

The equipment according to the present embodiment may be transportation equipment such as vehicles, ships, and aircraft. The mechanical apparatus in transportation equipment can be used as a moving apparatus. The equipment as transportation equipment is suitable for equipment that transports the semiconductor apparatus or equipment that assists and/or automates operation (driving) using the imaging function. The processing apparatus for assisting and/or automating operation (driving) can perform processing for operating the mechanical apparatus serving as a moving apparatus based on information obtained by the semiconductor apparatus.

The present embodiment has been described by using the photoelectric conversion device as an example of the semiconductor device. However, other semiconductor devices may be used. Both a photoelectric conversion device and other semiconductor devices may be used.

According to an embodiment of the present disclosure, a technique advantageous to a method for manufacturing a semiconductor device where a plurality of chips is arranged on a substrate can be provided.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-227251, filed Dec. 24, 2024, which is hereby incorporated by reference herein in its entirety.

What is claimed is:

1. A method for manufacturing a semiconductor device including a first substrate, on which a plurality of parts is arranged, and a plurality of chips disposed on the first substrate to correspond to the respective parts, the method comprising:
preparing a member including the first substrate and the plurality of chips disposed on the substrate;
forming a first film having a flat top surface by applying a precursor onto the member so that an amount of precursor applied onto the chips is less than an amount of precursor applied onto another portion; and
dicing the member,
wherein the forming the first film includes bringing a superstrate into contact with the precursor.

2. The method for manufacturing a semiconductor device according to claim 1, wherein forming the first film includes planarizing a top surface of the precursor and curing the precursor to have the flat top surface.

3. The method for manufacturing a semiconductor device according to claim 1, wherein the forming the first film includes curing the precursor with the superstrate in contact with the precursor.

4. The method for manufacturing a semiconductor device according to claim 1, further comprising, after the forming the first film, bonding a second substrate to the first film.

5. The method for manufacturing a semiconductor device according to claim 1, further comprising, before the dicing the member, bonding a second substrate to the first film and thinning the first substrate.

6. The method for manufacturing a semiconductor device according to claim 1, wherein the forming the first film includes applying the precursor so that the amount of precursor applied onto the chips is less than an amount of precursor applied onto a portion between the chips.

7. The method for manufacturing a semiconductor device according to claim 1, wherein the forming the first film includes applying the precursor so that the amount of precursor applied onto the chips is less than an amount of precursor applied onto chips different from the chips among the plurality of chips.

8. The method for manufacturing a semiconductor device according to claim 1, wherein the forming the first film includes applying the precursor so that the amount of precursor applied onto the plurality of chips is less than an amount of precursor applied onto another portion.

9. The method for manufacturing a semiconductor device according to claim 8, wherein the forming the first film includes applying the precursor so that the amount of precursor applied onto the plurality of chips is less than an amount of precursor applied onto a portion between the plurality of chips.

10. The method for manufacturing a semiconductor device according to claim 1,
wherein the plurality of parts includes a photoelectric conversion element, and
wherein the chips include a circuit configured to process a signal output from the photoelectric conversion element.

11. A method for manufacturing a semiconductor device including a first substrate, on which a plurality of parts is arranged, and a plurality of chips disposed on the first substrate to correspond to the respective parts, the method comprising:
preparing a member including the first substrate and the plurality of chips disposed on the first substrate;
forming a first film having a flat top surface by applying a precursor onto the member so that an amount of precursor applied onto the chips is less than an amount of precursor applied onto another portion; and
dicing the member,
wherein the forming the first film includes curing the precursor with a second substrate in contact with the precursor, and bonding the second substrate to the first film.

12. The method for manufacturing a semiconductor device according to claim 11, wherein the forming the first film includes planarizing a top surface of the precursor and curing the precursor to have the flat top surface.

13. The method for manufacturing a semiconductor device according to claim 11, further comprising, after the forming the first film, bonding the second substrate to the first film.

14. The method for manufacturing a semiconductor device according to claim 11, further comprising, before the dicing the member, bonding the second substrate to the first film and thinning the first substrate.

15. The method for manufacturing a semiconductor device according to claim 11, wherein the forming the first film includes applying the precursor so that the amount of precursor applied onto the chips is less than an amount of precursor applied onto a portion between the plurality of chips.

16. The method for manufacturing a semiconductor device according to claim 11, wherein the forming the first film includes applying the precursor so that the amount of precursor applied onto the chips is less than an amount of precursor applied onto chips different from the chips among the plurality of chips.

17. The method for manufacturing a semiconductor device according to claim 11, wherein the forming the first film includes applying the precursor so that the amount of precursor applied onto the plurality of chips is less than an amount of precursor applied onto another portion.

18. The method for manufacturing a semiconductor device according to claim 17, wherein the forming the first film includes applying the precursor so that the amount of precursor applied onto the plurality of chips is less than an amount of precursor applied onto a portion between the plurality of chips.

19. The method for manufacturing a semiconductor device according to claim 11,
wherein the plurality of parts includes a photoelectric conversion element, and
wherein the chips include a circuit configured to process a signal output from the photoelectric conversion element.
